(19) United States
(12) Patent Application Publication
(10) Pub. No.: US 2008/0308880 A1
(43) Pub. Date: Dec. 18, 2008

(54) SEMICONDUCTOR DEVICE

(75) Inventor: Satoshi Inaba, Kanagawa-ken (JP)

Correspondence Address: AMIN, TUROCY & CALVIN, LLP, 127 Public Square, 57th Floor, Key Tower, CLEVELAND, OH, 44114, US

(73) Assignee: KABUSHIKI KAISHA TOSHIBA, Tokyo (JP)

(21) Appl. No.: 12/139,762

(22) Filed: Jun. 16, 2008

(30) Foreign Application Priority Data
Jun. 15, 2007 (JP) 2007-158905

(51) Int. Cl. H01L 27/088

(52) U.S. Cl. 257/401; 257/E29.255

(57) ABSTRACT

In one aspect of the present invention, a semiconductor device, may include a fin formed of a semiconductor layer protruding straight from a semiconductor substrate, the fin includes straight portion which extends in a direction in a plan view and a bent portion which extends in a direction different from the direction, the straight portion and the bent portion being continuously connected, a gate insulating film provided on side surfaces of the straight portion of the fin, a gate electrode provided on the gate insulating film, source and drain regions provided in the straight portion of the fin so as to sandwich the gate electrode, a contact region provided on the straight portion of the fin and the bent portion of the fin, the contact region being electrically connected to one of the source and drain regions, and a contact member provided on the contact region of the fin so as to in contact with both of the straight portion and the bent portion of the contact region.

### CROSS REFERENCE TO RELATED APPLICATION

This application is based upon and claims the benefit of priority from Japanese Patent Application No. 2007-158905, filed on Jun. 15, 2007, the entire contents of which are incorporated herein by reference.

### BACKGROUND

In recent years, LSIs each formed on a silicon substrate have been improved in performance along with the miniaturization of the elements used therein. In MOS-type field effect transistors (hereinafter referred to as MOSFETs) used in logic circuits or memory devices such as an SRAM, such improvement in performance is achieved based on the so-called scaling rule through reductions of the gate lengths and the gate insulating film thicknesses. Recently, as a kind of MIS-type semiconductor devices having three dimensional structures, a double-gate fully-depleted-SOI MOSFET is proposed for improving a cut-off property in a short channel region having a channel length L not more than 30 nm. The double-gate fully-depleted-SOI MOSFET is manufactured as follows. Firstly, a silicon substrate in a silicon-on-insulator (SOI) substrate is cut into narrow strips, which are to serve as protruding regions (referred to as fin regions). Then, a gate electrode is crossed over each of the thus-cut-off protruding regions, so that the top and side surfaces of the protruding region serve as channels (refer to, for example, Japanese Patent Application Publication No. Hei 2-263473, Japanese Patent No. 2768719, D. Hisamoto et al., “A Folded-Channel MOSFET for Deep-sub-tenth Micron Era,” IEDM'98, p. 1032, X. Huang et al., “Sub 50-nm FinFET: PMOS,” IEDM'99, p. 67).

A MOSFET in which channels are formed on side surfaces of a fin region by using a gate electrode crossed over the fin region (hereinafter, this type of a MOSFET is referred to as a FinFET) is a type of the fully-depleted-SOI MOSFET. Accordingly, it is required that the fin width be smaller than the gate length to suppress short channel effect in a FinFET. For example, in a single-gate MOSFET using a fully-depleted SOI substrate, the thickness of each channel layer needs be reduced to the one-third of the gate length (refer to, for example, H. S. Philip Wong et al., “Device Design Considerations for Double-Gate, Ground-Plane, and Single-Gated Ultra-Thin SOI MOSFET's at the 25 nm Channel Length Generation,” IEDM'98 pp. 407-410), and in a FinFET, the thickness of each channel layer needs to be simply reduced to approximately two times of the above value, i.e. approximately two-third of the gate length. For example, in an element having a gate length of 20 nm, the fin width should be approximately 12 to 15 nm. This means that the minimum dimension determined by the lithography shifts to the fin width in the FinFET while the minimum dimension determined by the lithography is the gate length in the conventional planar MOSFET. Accordingly, the FinFET requires a stricter dimension control.

Using such elements to construct, for example, the circuit of an SRAM cell has been involving the following problems. Firstly, it is difficult to control the dimensions of the fin widths. Secondly, it is also difficult to control differences in threshold voltage between the transistors in the SRAM cell so that the current can be set to an appropriate value. The latter difficulty is particularly serious in a SRAM cell, since the SRAM cell has active regions of complicated shapes. As a result, this configuration has had a disadvantage of having an unstable operating point since a sufficient static noise margin (SMN) is difficult to be ensured in the configuration (refer to, for example, E. J. Nowak et al., “A Functional FinFET-DGCMOS SRAM Cell,” IEDM Tech. Dig., pp. 411-414, 2002).

Meanwhile, the active regions may be formed by a sidewall pattern transfer method. In this method, a dummy pattern made of a first material is firstly formed on a silicon substrate, and thereafter a second material film is stacked thereon. Then, the second material film is etched back using a reactive ion etching (RIE) method or the like, so that the second material film can remain selectively on sidewalls of the dummy pattern. The thickness of the remaining film is determined by the thickness of the second material film stacked in the earlier step and an etching time of the etching-back process, thus allowing relatively accurate dimensional control. Accordingly, the thus-remaining second material film can be used as a patterning mask. Thus, the second material film formed by this method has smaller dimensional variation than the conventional mask (resist) formed through the combination of the application of a resist and light exposure (refer to, for example, A. Kaneko et al., “Sidewall Transfer Process and Selective Gate Sidewall Spacer Formation Technology for Sub-15 nm FinFET with Elevated Source/Drain Extension,” IEDM Tech. Dig., pp. 863-866, 2005).

### SUMMARY

Aspects of the invention relate to an improved semiconductor device.

In one aspect of the present invention, a semiconductor device, may include a fin formed of a semiconductor layer protruding straight from a semiconductor substrate, the fin includes straight portion which extends in a direction in a plan view and a bent portion which extends in a direction different from the direction, the straight portion and the bent portion being continuously connected, a gate insulating film provided on side surfaces of the straight portion of the fin, a gate electrode provided on the gate insulating film, source and drain regions provided in the straight portion of the fin so as to sandwich the gate electrode, a contact region provided on the straight portion of the fin and the bent portion of the fin, the contact region being electrically connected to one of the source and drain regions, and a contact member provided on the contact region of the fin so as to in contact with both of the straight portion and the bent portion of the contact region.

In one aspect of the present invention, a semiconductor device, may include a load transistor provided on a semiconductor substrate, a transfer transistor provided on the semiconductor substrate, and a driver transistor provided on the semiconductor substrate, wherein the driver transistor includes, first and second fins each formed of a semiconductor layer protruding straight from the semiconductor substrate, each of the first and second fins includes straight portion which extends in a direction in a plan view and a bent portion which extends in a direction different from the direction, the straight portion and the bent portion being continuously connected, the first fin and the second fins extending substantially same direction, a gate insulating film provided on side surfaces of the straight portion of each of the first and second fins, a gate electrode provided on the gate insulating film, first source and drain regions provided in the straight portion of the first fin so as to sandwich the gate electrode, second source and drain regions provided in the straight portion of the second fin so as to sandwich the gate electrode, a contact region provided on the straight portion of the first and second fins and the bent portion of the first and second fins, the contact region being electrically connected to one of the first and second source region and first and second drain region, and a contact member provided on the contact region of the first and second fins so as to in contact with both of the straight portion and the bent portion of the contact region.

### BRIEF DESCRIPTIONS OF THE DRAWINGS

A more complete appreciation of the invention and many of the attendant advantages thereof will be readily obtained as the same becomes better understood by reference to the following detailed description when considered in connection with the accompanying drawings.

FIG. 1A shows the structure of a typical double-gate MOSFET, and FIG. 1B shows electrostatic potential thereof.

FIG. 2 is a perspective view showing the structure of the FinFET.

FIG. 3 is a circuit diagram of a six-transistor SRAM cell constructed of six transistors.

FIG. 4 shows the layout of a SRAM cell according to a first embodiment.

FIGS. 5A and 5B each are a conceptual diagram of the fin regions each having bent portions in the SRAM cell.

FIGS. 6 to 13 each are a plan view showing an example of a method of manufacturing (patterning) the SRAM cell according to the first embodiment.

FIG. 14 shows the layout of a SRAM cell according to the second embodiment.

FIGS. 15 to 22 each are a plan view showing an example of a method of manufacturing (patterning) the SRAM cell according to the second embodiment.

FIG. 23 shows the layout of a SRAM cell according to the third embodiment.

FIGS. 24 to 32 each are a plan view showing an example of a method of manufacturing (patterning) the SRAM according to the third embodiment.

FIGS. 33 to 36 show processes of forming a layout in which one of the two fin regions of each driver transistor is disposed in line with the fin region of the corresponding transfer transistor.

### DETAILED DESCRIPTION

Various connections between elements are hereinafter described. It is noted that these connections are illustrated in general and, unless specified otherwise, may be direct or indirect and that this specification is not intended to be limiting in this respect.

Embodiments of the present invention will be explained with reference to the drawings as next described, wherein like reference numerals designate identical or corresponding parts throughout the several views.

### First Embodiment

FIG. 1A shows the structure of a typical double-gate MOSFET, and FIG. 1B shows electrostatic potential thereof.

In a double-gate MOSFET, as shown in FIG. 1A, the same voltage is simultaneously applied to a top gate (or called front gate) electrode 1 and a back gate electrode 2. Therefore, as shown in FIG. 1B, when potential is seen in cross section taken in a direction perpendicular to the channel, it can be understood that a Fermi level is pulled up at the top and back gate electrodes 1 and 2, so that channels are formed near the side surfaces of the top and back gate electrodes 1 and 2. In usual, a transistor called FinFET has a structure in which an equal potential is simultaneously applied to the top and back gate electrodes, and accordingly is a type of double-gate transistors in a narrow sense.

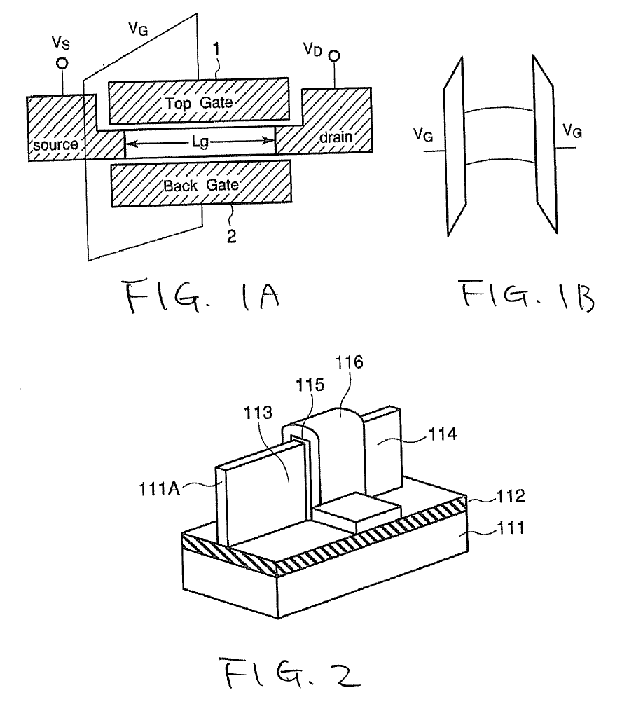

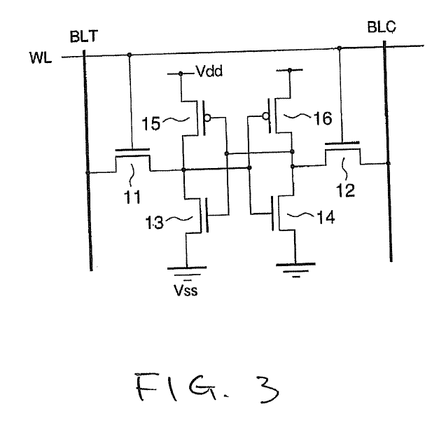

FIG. 2 is a perspective view showing the structure of the FinFET. As shown in FIG. 2, a protruding region (fin region) 111A and an insulating film 112 are formed on a semiconductor substrate 111. A source 113 and a drain 114 are formed on the side surfaces of the protruding region 111A. A gate insulating film 115 is formed on the protruding region 111A between the source 113 and the drain 114. Furthermore, on the gate insulating film 115, a gate electrode 116 is formed so as to cross over the protruding region 111A.

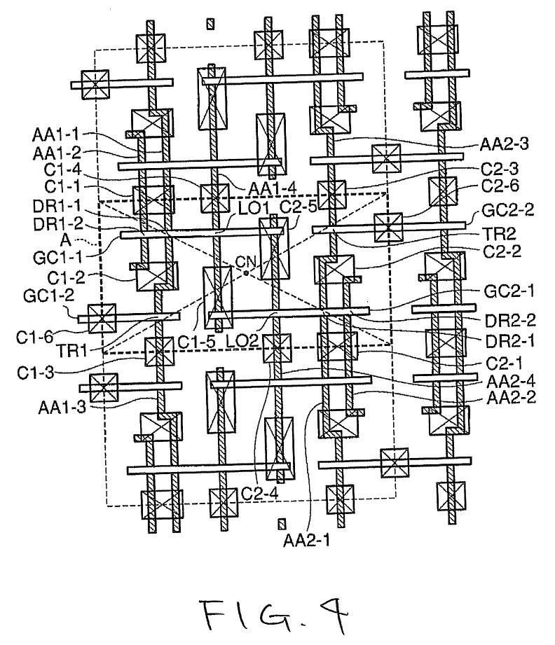

FIG. 3 is a circuit diagram of a six-transistor SRAM cell constructed of six transistors.

In this circuit, an n-channel MOS field effect transistor (hereinafter referred to as nFET) 11 and nFET 12 which are respectively connected to bit lines BLT and BLC are called transfer transistors (or pass-gate transistors). NFETs 13 and 14 which are connected to ground potential terminals Vss are called driver transistors (or pull-down transistors) A p-channel MOS field effect transistor (hereinafter referred to as pFET) 15 and pFET 16 which are connected to power supply potential terminals Vdd are called load transistors (or pull-up transistors) In usual, the stability of the SRAM cell depends on a ratio value (β-ratio) of current drive capability between the driver transistors and the transfer transistors. The stability of the SRAM cell is gained by setting current drive capability of the driver transistors larger than that of the transfer transistors. This is actually achieved by increasing the channel width of each driver transistor and by appropriately controlling the threshold voltages Vt.

However, employing the aforementioned FinFET as each transistor of the six transistor SRAM cell involves the following difficulties.

(A) The ratio of the current drive capability between the nFETs serving as the driver transistors and the nFETs serving as the transfer transistors cannot be controlled by adjusting the channel widths of the transistors unlike the conventional transistors. This is because the channel width of the FinFET is determined by the height of the silicon protruding region that is the fin region. In general, it is difficult to vary the height of the silicon protruding region from transistor to transistor.

(B) A method of changing the gate length from transistor to transistor will be effective for adjusting a current drive capability of each transistor. However, this method makes it difficult to assure a sufficient β-ratio (current drive capability ratio). Furthermore, this method causes the transistors in the SRAM cell to have different gate lengths, thus making the critical dimension (CD) control in lithography difficult in the SRAM cell.

Therefore, in each of embodiments of the present invention, the following method is employed as a method of constructing an SRAM cell by using FinFETs. Specifically, each of the FinFETs serving as the driver transistors is formed by using two fin regions, and each of the FinFETs serving as the transfer transistors is formed by using one fin region. This method makes it possible to reduce dimensional variation in the SRAM cell while improving the β-ratio (current drive capability ratio).

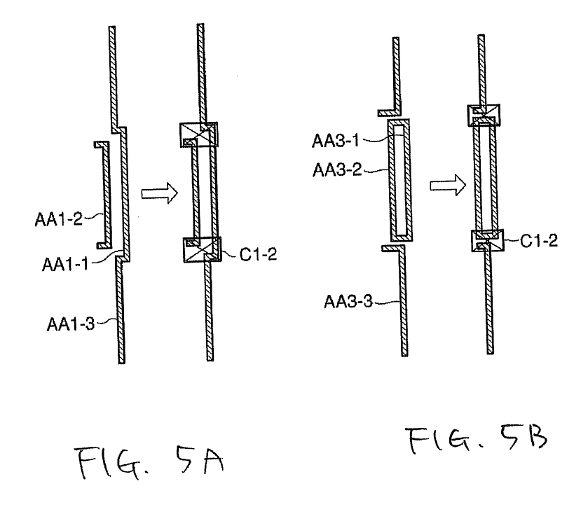

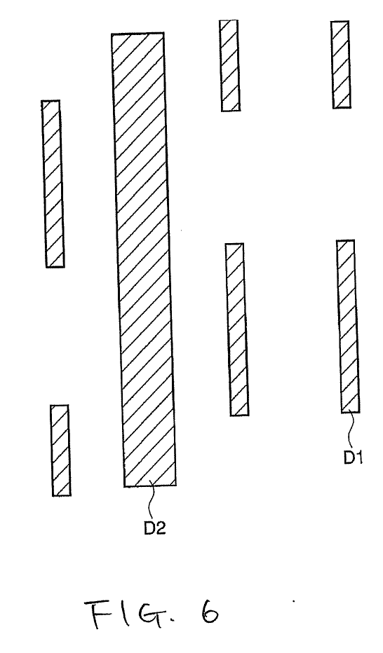

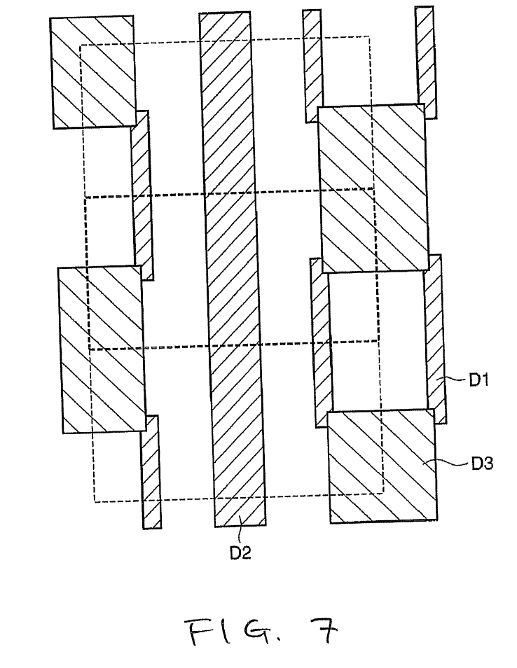

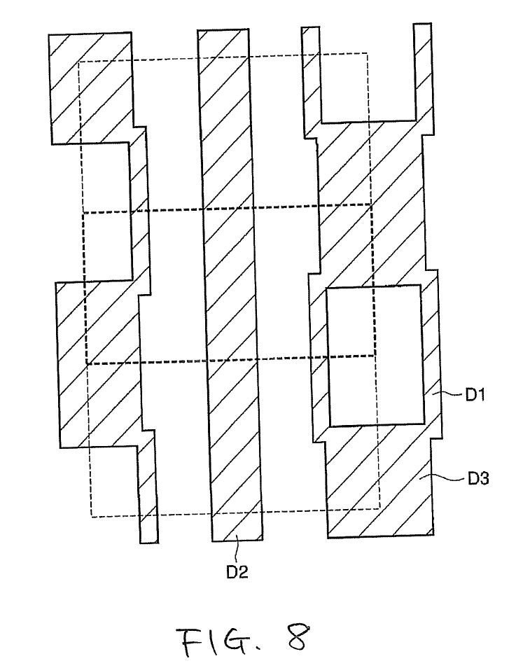

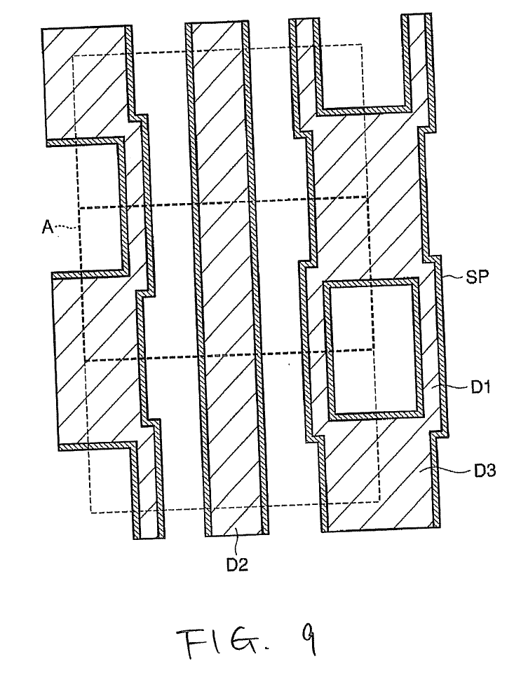

FIG. 4 shows the layout of a SRAM cell according to a first embodiment. A section enclosed by a dashed line A corresponds to a unit cell.

In the SRAM cell A, disposed are transistors including a driver transistor DR1-1 and DR1-2, a transfer transistor TR1, and a load transistor LO1 as well as a driver transistor DR2-1 and DR2-2, a transfer transistor TR2, and a load transistor LO2. With respect to the center point CN of the SRAM cell, the driver transistor DR1-1 and DR1-2 and the driver transistor DR2-1 and DR2-2, the transfer transistors TR1 and TR2, and the load transistors LO1 and LO2 are symmetrically disposed.

Fin regions AA1-1, AA1-2, AA1-3 and AA1-4 are disposed so as to extend respectively on the driver transistor DR1-1 and DR1-2, the transfer transistor TR1, and the load transistor LO1 in the channel length directions of the transistors. On the fin regions AA1-1, AA1-2 and AA1-4, a gate electrode GC1-1 is formed with a gate insulating film disposed in between. On the fin region AA1-3, a gate electrode GC1-2 is formed with a gate insulating film disposed in between.

On parts of the fin regions AA1-1 and AA1-2, a contact region C1-1 is formed. On end parts of the fin regions AA1-1, AA1-2 and AA1-3, a contact region C1-2 is formed. On a part of the fin region AA1-3, a contact region C1-3 is formed. On a part of the fin region AA1-4, a contact region C1-4 is formed. On an end part of the fin region AA1-4 and a gate electrode GC2-1 to be described below, a contact region C1-5 is formed. On the gate electrode GC1-2, a contact region C1-6 is formed. The fin region AA1-2 has a region (fringe) bent in a direction different from the channel length direction (for example, a direction approximately perpendicular to the channel length direction) in its end part on which the contact region C1-2 is formed. Similarly, each of the fin regions AA1-1 and AA1-3 has a region bent in a direction different from the channel length direction (for example, a direction approximately perpendicular to the channel length direction) in its end part on which the contact region C1-2 is formed.

Fin regions AA2-1, AA2-2, AA2-3 and A2-4 are disposed so as to extend respectively on the driver transistor DR2-1 and DR2-2, the transfer transistor TR2, and the load transistor LO2 in the channel length directions of the transistors. On the fin regions AA2-1, AA2-2 and AA2-4, the gate electrode GC2-1 is formed with a gate insulating film disposed in between. On the fin region AA2-3, a gate electrode GC2-2 is formed with a gate insulating film disposed in between.

On parts of the fin regions AA2-1 and AA2-2, a contact region C2-1 is formed. On end parts of the fin regions AA2-1, AA2-2 and AA2-3, a contact region C2-2 is formed. On a part of the fin region AA2-3, a contact region C2-3 is formed. On a part of the fin region AA2-4, a contact region C2-4 is formed. On an end part of the fin region AA2-4 and the gate electrode GC1-1, a contact region C2-5 is formed. On a gate electrode GC2-2, a contact region 2-6 is formed. The fin region AA2-2 has a region bent in a direction different from the channel length direction (for example, a direction approximately perpendicular to the channel length direction) in its end part on which the contact region C2-2 is formed. Similarly, each of the fin regions AA2-1 and AA2-3 has a region bent in a direction different from the channel length direction (for example, a direction approximately perpendicular to the channel length direction) in its end part on which the contact region C2-2 is formed. Note that, on each contact region, a contact member is formed to connect the corresponding fin region and an upper-layer interconnection.

The characteristics of the SRAM cell according to the first embodiment of the present invention are as follows.

(1) Since a dummy pattern for sidewall pattern transfer are formed through double exposure, an SRAM cell having a β-ratio of 2 can be formed through a sidewall pattern transfer process. Although a dummy pattern for an SRAM cell including driver transistors each having only one fin region can be formed in a relatively simple way, forming a dummy pattern for an SRAM cell including driver transistors each having two fin regions requires some measures to be described in embodiments of the present invention.

(2) Each of the n-type FinFETs serving as the driver transistors includes two fin regions having bent portions (bent Fins), and these two approximately parallel fin regions are connected through the contact member in each contact region (metal interconnect region).

(3) A parasitic resistance can be reduced since the contact area between (side surfaces of) an active region serving as each fin region and the contact member can be increased as compared to the case of a usual borderless contact.

(4) Since the contact region C1-1 of the driver transistor is disposed on two fin regions asymmetrically with respect to the fin regions, the resistance can be reduced while a clearance between the contact regions C1-1 and C1-4 is ensured.

(5) Each pair of the driver transistors and the transfer transistors are disposed in an offset layout instead of being disposed in line with each other. This enables a layout having contact-to-contact clearances satisfying the minimum design rule in an SRAM cell including transistors each having two fin regions.

FIGS. 5A and 5B each are a conceptual diagram of the fin regions each having bent portions in the SRAM cell. As shown in FIG. 5A, each of the fin regions AA1-1, AA1-2 and AA1-3, which is usually formed in a straight line, is bent in a direction parallel to the gate electrodes, in some portions. In other words, each of the fin regions is bent in a fin width direction, in portions extended in the channel length direction, of the fin region. Moreover, each of the fin regions intersects with the contact region C1-2 at one of the bent portions. The pattern formed of the fin regions AA1-1, AA1-2 and AA1-3 which is shown in FIG. 5A may be modified to a pattern formed of fin regions AA3-1, AA3-2 and AA3-3 which is shown in FIG. 5B.

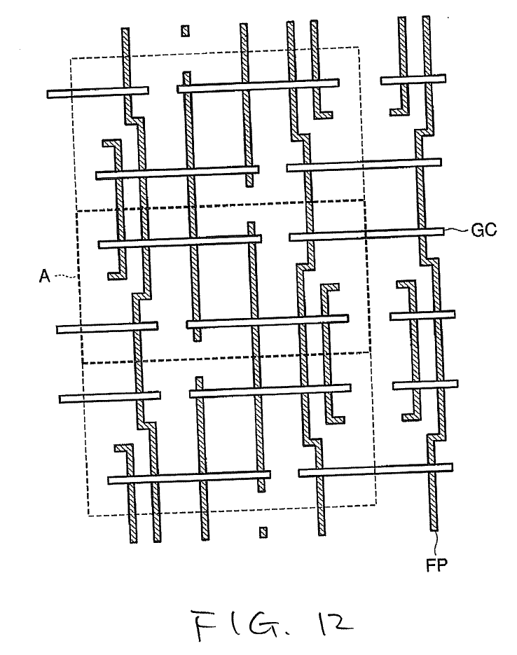

When a contact region is formed on the bent portions of the fin regions as described above, the contact area between side surfaces of each of the fin regions and the contact member can be increased in the contact region. Consequently, the parasitic resistance can be reduced. Moreover, employing this configuration in a SRAM cell makes it possible to connect a transistor including one fin region with a transistor including two fin regions in the contact region. To be described below, this configuration can be applied to the case in which active regions are formed using a sidewall pattern transfer method. Actually, the thus-formed sidewall pattern needs to be trimmed so as to have a desired shape (refer to FIG. 10 and the like). Accordingly, after considering misalignment of a trimming mask, the shape of each active region is limited to a shape having the aforementioned fringe.

FIGS. 6 to 13 each are a plan view showing an example of a method of manufacturing (patterning) the SRAM cell according to the first embodiment.

Firstly, an insulating film to serve as dummy patterns is formed on a semiconductor substrate, and a negative resist film is subsequently applied on the insulating film. Then, the resist film is exposed so that first dummy patterns D1 and D2 shown in FIG. 6 can be transferred thereon. Here, the resist film is not developed, but the patterns are only formed as latent image. Thereafter, the resist film is further exposed so that a second dummy pattern D3 shown in FIG. 7 can be transferred thereon (double exposure). Note that the dummy patterns D1 and D3 must be overlapped with each other in some region in this embodiment. The dummy pattern D2 may be transferred on the resist film in the second-round exposure process shown in FIG. 7.

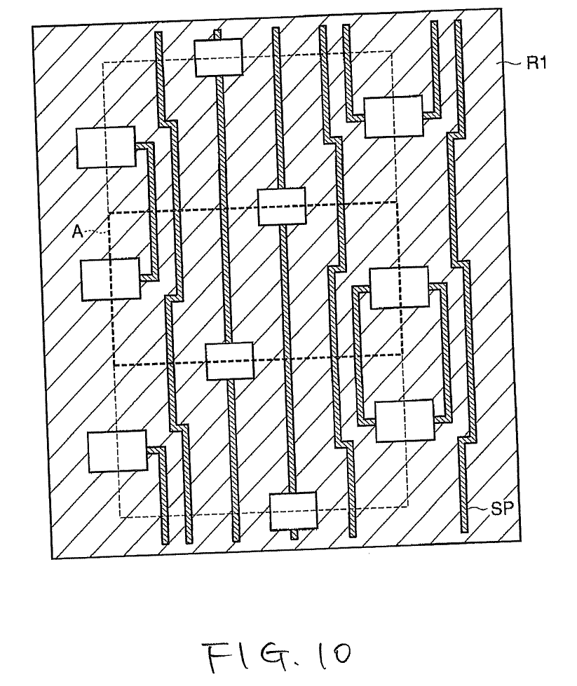

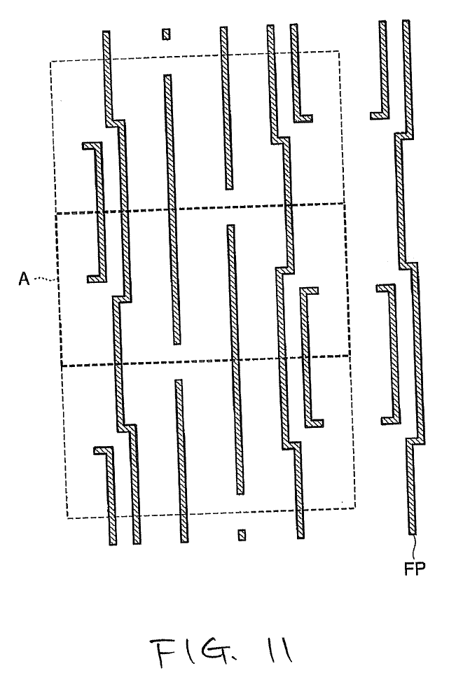

Then, the thus-patterned resist film is developed, and thereafter the insulating film is patterned so that the first and second dummy patterns D1, D2 and D3 shown in FIG. 8 can be formed. The section enclosed by a dashed line A represents an SRAM cell (unit cell). Thereafter, a material to serve as sidewall patterns are stacked on the dummy patterns D1, D2 and D3, and the semiconductor substrate. Subsequently, the above material is etched back so that sidewall patterns SP can remain on the sidewalls of the dummy patterns D1, D2 and D3 as shown in FIG. 9.

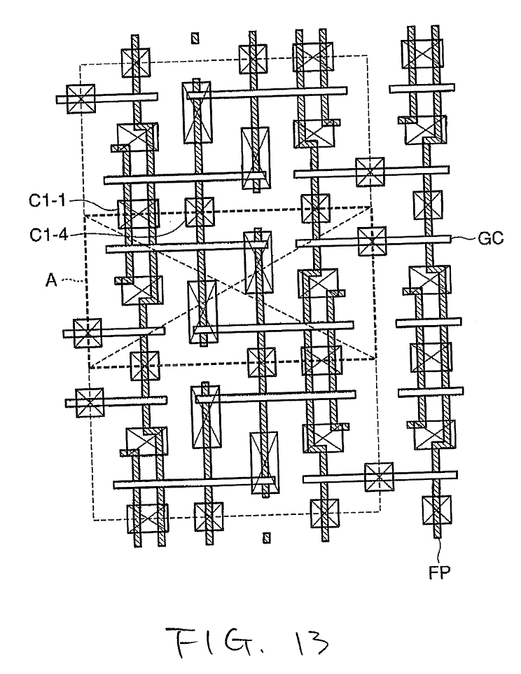

Then, after the dummy patterns D1, D2 and D3 are removed, unnecessary portions of the sidewall patterns SP are removed by using, as a mask, a resist film R1 shown in FIG. 10. Furthermore, the silicon active regions under the unnecessary portions of the sidewall patterns SP are also removed by using the resist film R1 as a mask. Thereafter, the resist film R1 shown in FIG. 10 is peeled off. Subsequently, fin region patterns are formed by using the sidewall patterns SP as a mask. FIG. 11 shows the thus-formed fin region patterns FP. These fin region patterns FP are formed of the silicon active regions, almost all of which have the same size (width).

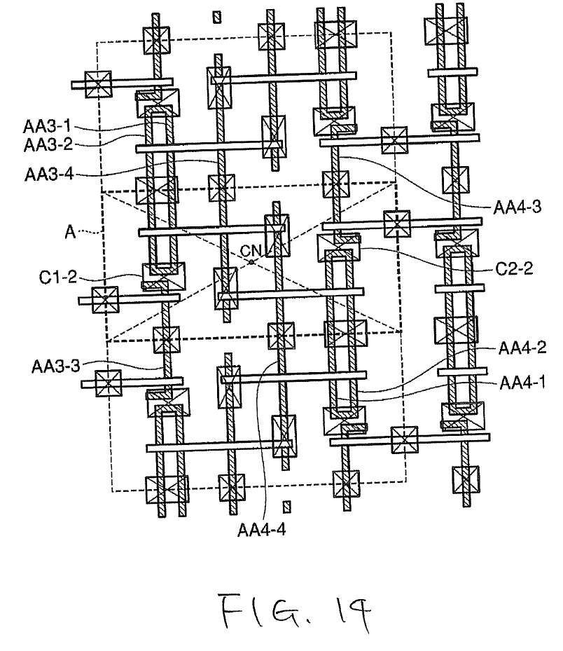

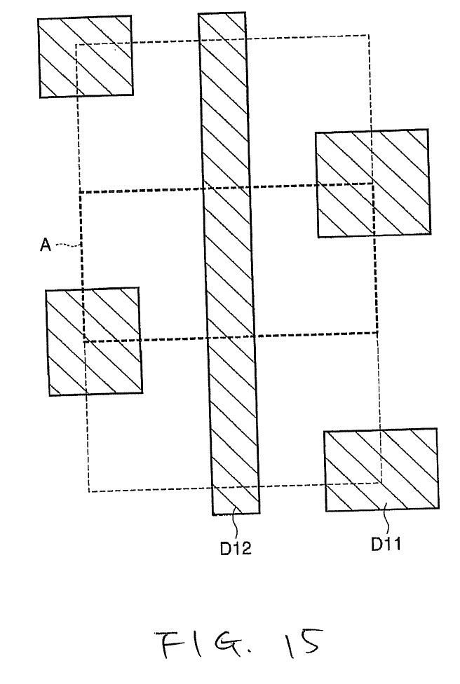

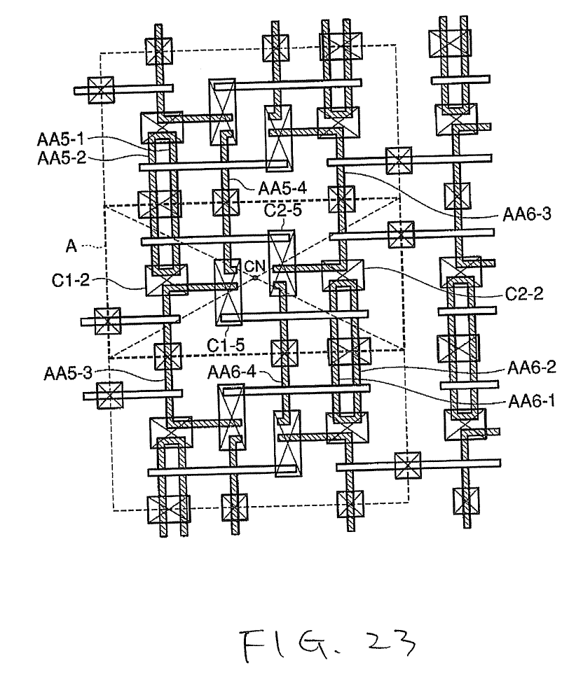

Then, a gate insulating film, and a film to serve as gate electrodes are sequentially formed. Thereafter, these films are patterned to form the gate electrodes GC as shown in FIG. 12. The gate electrodes GC are also formed by a sidewall pattern transfer method. Accordingly, all the transistors have the same gate length. Moreover, after the entire area is covered with an unillustrated insulating film, the insulating film is patterned to form contact regions as shown in FIG. 13. Here, only the contact region C1-1, to which the ground potential Vss is supplied, of the driver transistor is disposed in an offset layout. In other word, the contact region C1-1 is displaced from the middle of the fin regions AA1-1 and AA1-2 in a direction away from the contact region C1-4 that is disposed adjacent to the contact region C1-1 and to which a power supply voltage Vdd is supplied. With this arrangement, a necessary and sufficient distance can be maintained between the contact regions C1-1 and C1-4. Thereafter, metal interconnections shown in FIG. 22 to be described below are formed with an interlayer insulating film disposed in between.

Note that the dummy patterns are formed by using a negative resist film herein, but the dummy patterns may be formed by using one or more positive resist films. For example, after a positive resist film is applied on the insulating film, the resist film is exposed and developed so that the dummy patterns D1 and D2 shown in FIG. 6 can be transferred thereon. Then, after another positive resist film is further applied thereon, this resist film is exposed and developed so that the dummy pattern D3 shown in FIG. 7 can be transferred thereon. A resist film for forming the dummy patterns shown in FIG. 8 may be formed in this manner. Alternatively, for example, after a positive resist film is applied on the insulating film, the resist film is exposed and developed so that the dummy patterns D1, D2 and D3 shown in FIGS. 6 and 7 can be transferred thereon all at once. A resist film for forming the dummy patterns shown in FIG. 8 may be formed by this method.

In a semiconductor device containing the SRAM cell manufactured as described above, the dimensional control of the fin widths is simplified while differences in threshold voltage between the transistors in the SRAM cell can be controlled so that the current can be set to an appropriate value. Thus, the first embodiment makes it possible to manufacture a semiconductor device that includes an SRAM cell using FinFETs and having a sufficient static noise margin.

### Second Embodiment

Hereinafter, a second embodiment of the present invention will be described. The same components as those in the configuration according to the aforementioned first embodiment are provided with the same reference symbols, and description thereof will be omitted. The second embodiment is different from the first embodiment in the shapes of the fin regions AA1-1, AA1-2 and AA1-3 as well as their symmetrical counterparts, fin regions AA2-1, AA2-2 and AA2-3. In the other points, the second embodiment has the same configuration as the first embodiment.

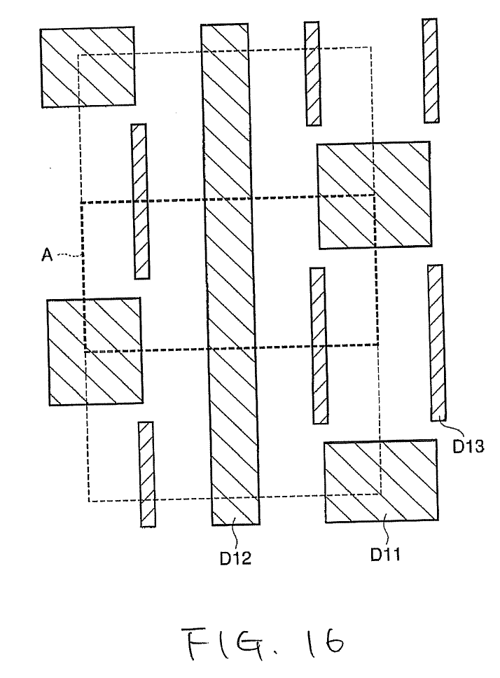

FIG. 14 shows the layout of a SRAM cell according to the second embodiment. In a contact region C1-2, fin regions AA3-1 and AA3-2 are bent in a direction approximately perpendicular to the channel length direction, and thereby connected with each other. In the contact region C1-2, a fin region AA3-3 is bent in the direction that is approximately perpendicular to the channel length direction and that is toward the side opposite to the center point CN as shown in FIG. 14. As shown in FIG. 14, a fin region AA3-4 is disposed in the channel length direction. Description of fin regions AA4-1, AA4-2, AA4-3 and AA4-4 is omitted here, since the fin regions AA3-1 and AA4-1, AA3-2 and AA4-2, AA3-3 and AA4-3, and AA3-4 and AA4-4 are symmetrically formed with respect to the center point CN of the SRAM cell.

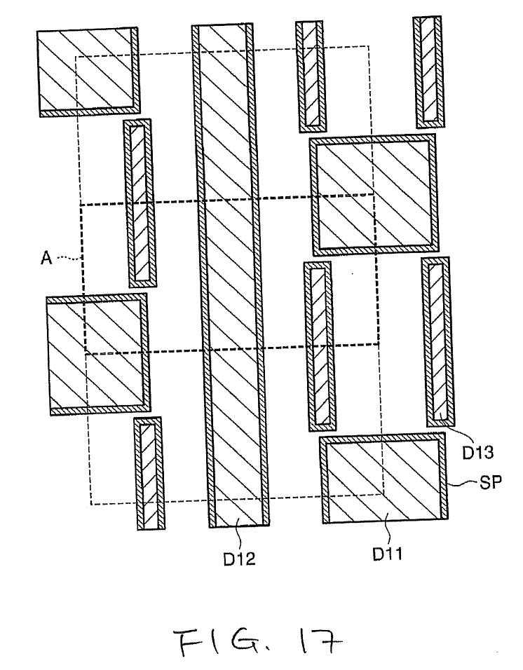

FIGS. 15 to 22 each are a plan view showing an example of a method of manufacturing (patterning) the SRAM cell according to the second embodiment.

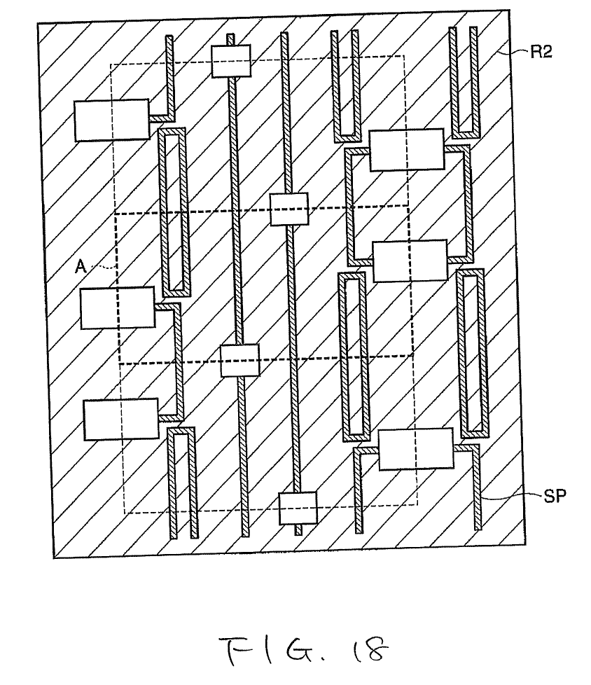

Firstly, an insulating film to serve as dummy patterns is formed on the semiconductor substrate, and a negative resist film is subsequently applied on the insulating film. Then, the resist film is exposed so that first dummy patterns D11 and D12 shown in FIG. 15 can be transferred thereon. Here, the resist film is not developed, but the patterns are only formed as latent image. Thereafter, the resist film is further exposed so that a second dummy pattern D13 shown in FIG. 16 can be transferred thereon (double exposure). Note that the dummy patterns D11 and D13 are not overlapped with each other in this embodiment. This arrangement eliminates the need to take proximity correction into account, thus allowing the patterns to be sharply formed. The dummy pattern D12 may be transferred on the resist film in the second-round exposure process shown in FIG. 16.

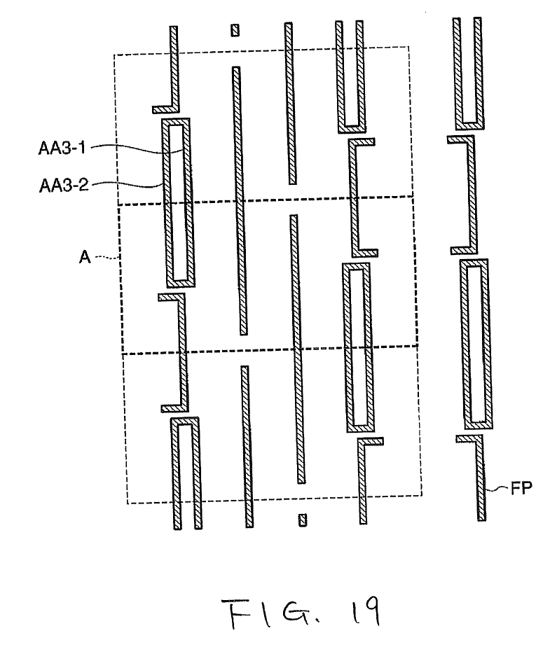

Then, the thus-patterned resist film is developed, and thereafter the insulating film is patterned so that the first and second dummy patterns D11, D12 and D13 shown in FIG. 17 can be formed. Thereafter, a material to serve as sidewall patterns are stacked on the dummy patterns D11, D12 and D13, and the semiconductor substrate. Subsequently, the above material is etched back so that sidewall patterns SP can remain on the sidewalls of the dummy patterns D11, D12 and D13 as shown in FIG. 17.

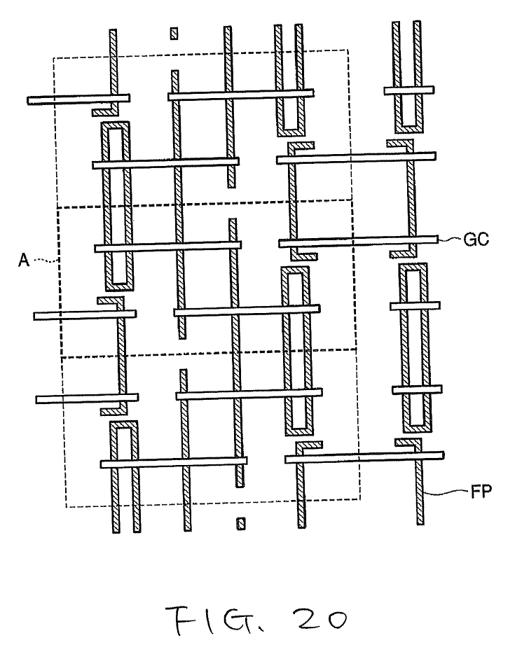

Then, after the dummy patterns D11, D12 and D13 are removed, unnecessary portions of the sidewall patterns SP are removed by using, as a mask, a resist film R2 shown in FIG. 18. Furthermore, the silicon active regions under the unnecessary portions of the sidewall patterns SP are also removed by using the resist film R2 as a mask. Thereafter, the resist film R2 shown in FIG. 18 is peeled off. Subsequently, fin region patterns are formed by using the sidewall patterns SP as a mask. FIG. 19 shows the thus-formed fin region patterns FP. These fin region patterns FP are formed of the silicon active regions, almost all of which have the same size (width). The two fin regions AA3-1 and AA3-2 in a driver transistor are connected with each other by fin regions formed in the direction approximately perpendicular to the channel length direction. Note that the section enclosed by a dashed line A represents an SRAM cell (unit cell).

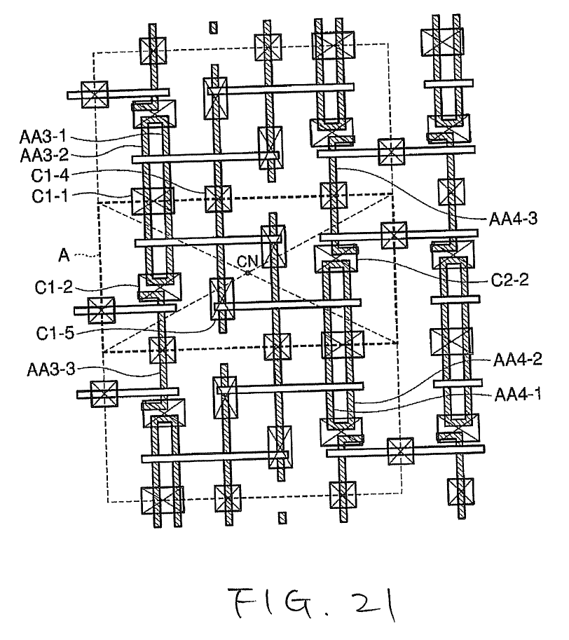

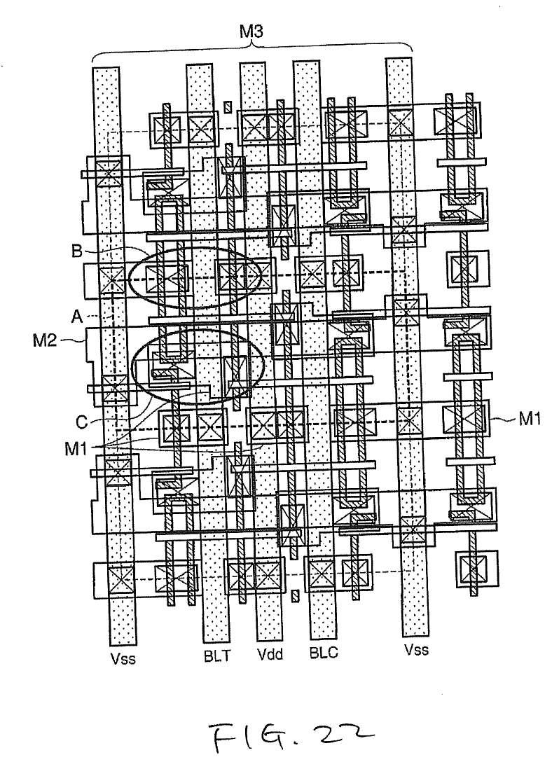

Then, a gate insulating film, and a film to serve as gate electrodes are sequentially formed. Thereafter, these films are patterned to form gate electrodes GC as shown in FIG. 20. The gate electrodes GC are also formed by a sidewall pattern transfer method. Accordingly, all the transistors have the same gate length. Moreover, after the entire area is covered with an unillustrated insulating film, the insulating film is patterned to form contact regions as shown in FIG. 21. Here, only a contact region C1-1, to which the ground potential Vss is supplied, of the driver transistor is disposed in an offset layout. In other word, the contact region C1-1 is displaced from the middle of the fin regions AA3-1 and AA3-2 in a direction away from a contact region C1-4 that is disposed adjacent to the contact region C1-1 and to which a power supply voltage Vdd is supplied. With this arrangement, a necessary and sufficient distance can be maintained between the contact regions C1-1 and C1-4. One of the fin regions formed in the direction approximately perpendicular to the channel length direction to connect the fin regions AA3-1 and AA3-2 in the driver transistor and the bent region, formed in the direction approximately perpendicular to the channel length direction, of the fin region AA3-3 in a transfer transistor are connected with each other through a contact member in the contact region C1-2.

Then, after an interlayer insulating film is formed on the semiconductor substrate, metal interconnections including first to third interconnections M1 to M3 are formed as shown in FIG. 22. A clearance between the contact regions 1-1 and 1-4 indicated by an ellipse B should definitely satisfy the minimum design rule. To this end, only the contact region C1-1 is disposed in the offset layout as described above so that the necessary and sufficient distance can be maintained between the contact regions C1-4 and C1-1. By contrast, the contact region C1-2 and a contact region C1-5 may be in contact with each other, since the contact regions C1-2 and C1-5 indicated by an ellipse C, which are to serve as output nodes in an inverter, are commonly connected through the first interconnection M1. Each of the contact members formed to be connected to Vss lines, a Vdd line, a BLT line and a BLC line, which are formed of the third interconnection M3, does not directly connect the first and third interconnections M1 and M3. Instead, each of these contact members is formed so as to connect the first and third interconnections M1 and M3 through an unillustrated relay pattern formed of the second interconnection M2.

Note that the dummy patterns are formed by using a negative resist film herein, but the dummy patterns may be formed by using one or more positive resist films, as similar to the first embodiment. For example, after a positive resist film is applied on the insulating film, the resist film is exposed and developed so that the dummy patterns D11 and D12 shown in FIG. 15 can be transferred thereon. Then, after another positive resist film is further applied thereon, this resist film is exposed and developed so that the dummy pattern D13 shown in FIG. 16 can be transferred thereon. A resist film for forming the dummy patterns D11, D12 and D13 may be formed in this manner. Alternatively, for example, after a positive resist film is applied on the insulating film, the resist film is exposed and developed so that the dummy patterns D11, D12 and D13 shown in FIGS. 15 and 16 can be transferred thereon all at once. A resist film for forming the dummy patterns D11, D12 and D13 may be formed by this method.

The second embodiment has the following characteristics in addition to the characteristics of the first embodiment.

(6) Since the second dummy pattern D13 and the first dummy patterns D11 and D12 are not overlapped with each other, misalignment tolerance of the dummy patterns can be increased as compared to the first embodiment.

(7) Since the narrow dummy pattern D13 is transferred onto the resist film in an exposure process separate from an exposure process for the wide and large dummy patterns D11 and D13, the lithography of the dummy patterns is simplified.

Therefore, in the above manufacturing method as well, an SRAM cell of a layout with a β-ratio of 2 can be formed through a sidewall pattern transfer method. This makes it possible to construct high-performance and almost uniform SRAM cells each having a sufficient static noise margin.

In a semiconductor device containing the SRAM cell manufactured as described above, the dimensional control of the fin widths is simplified while a difference in threshold voltage between the transistors in the SRAM cell can be controlled so that the current can be set to an appropriate value. Thus, the second embodiment also makes it possible to manufacture a semiconductor device that includes an SRAM cell using FinFETs and having a sufficient static noise margin.

### Third Embodiment

Hereinafter, a third embodiment of the present invention will be described. The same components as those in the configuration according to the aforementioned first embodiment are provided with the same reference symbols, and description thereof will be omitted. The third embodiment is configured of FinFETs formed on an SOI substrate. Furthermore, the third embodiment is different from the first embodiment in the shapes of the fin regions AA1-1, AA1-2 and AA1-3 as well as their symmetrical counterparts, fin regions AA2-1, AA2-2 and AA2-3. In the other points, the third embodiment has the same configuration as the first embodiment.

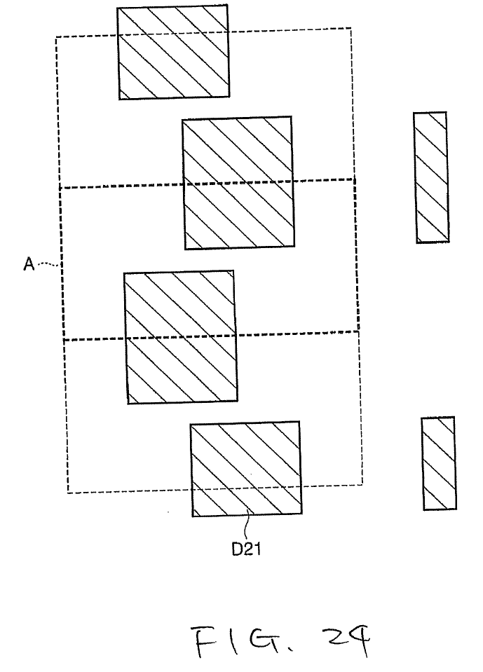

FIG. 23 shows the layout of a SRAM cell according to the third embodiment. In a contact region C1-2, fin regions AA5-1 and AA5-2 are bent in a direction approximately perpendicular to the channel length direction, and thereby connected with each other. In the contact region C1-2, a fin region AA5-3 is bent in the direction that is approximately perpendicular to the channel length direction and that is toward the side of the center point CN, thereby reaching a contact region C1-5, as shown in FIG. 23. As shown in FIG. 23, a fin region AA5-4 is also bent in the direction that is approximately perpendicular to the channel length direction and that is toward the side of the center point CN. Description of fin regions AA6-1, AA6-2, AA6-3 and AA6-4 is omitted here, since the fin regions AA5-1 and AA6-1, AA5-2 and AA6-2, AA5-3 and AA6-3, and AA5-4 and AA6-4 are symmetrically formed with respect to the center point CN of the SRAM cell.

The third embodiment has the following characteristics. In this embodiment, it is required that a silicon substrate on which FinFETs are formed be an SOI substrate.

(8) The drain regions of an nFET and a pFET (that is, regions to serve as output nodes in an inverter) are connected with each other by a fin region bent in the direction approximately perpendicular to the channel length direction. That is, regions to serve as output nodes in an inverter, which have so far been connected with each other through a share contact region and an interconnect region, are connected with each other by a fin region without employing an local interconnect (LI) region having a metal interconnection, in this embodiment. Accordingly, the number of metal interconnection layers can be reduced.

(9) Since an inverter is formed on an SOI substrate, a well separation width can be reduced irrespective of the withstand voltage of each well. Accordingly, an SRAM cell area can also be reduced.

(10) Each pFET serving as a load transistor is formed of a bent fin region (bent Fin), and is connected to a bent fin region of the corresponding nFET serving as a transfer transistor in the corresponding share contact region. This structure allows the pattern of an SRAM to be formed through an application of a sidewall pattern transfer process.

Therefore, this embodiment makes it possible to reduce an SRAM cell area and the number of the metal interconnection layers, and thereby to construct high-performance and almost uniform SRAM cells each having a sufficient static noise margin.

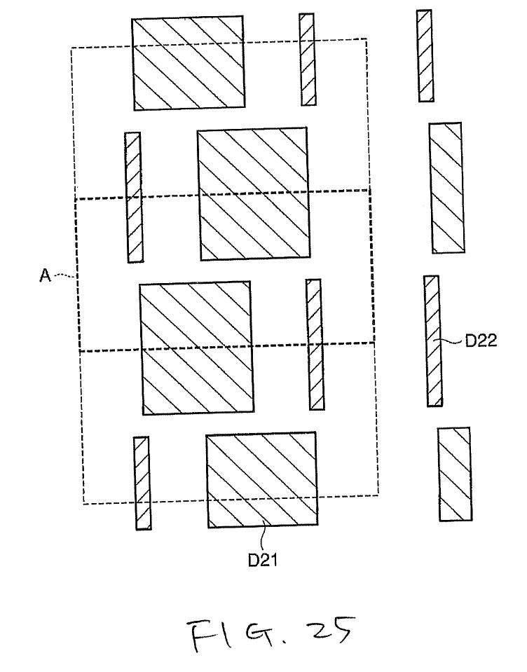

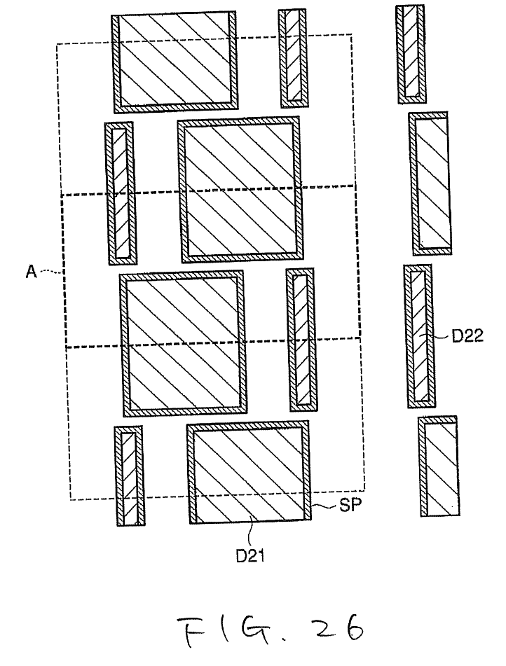

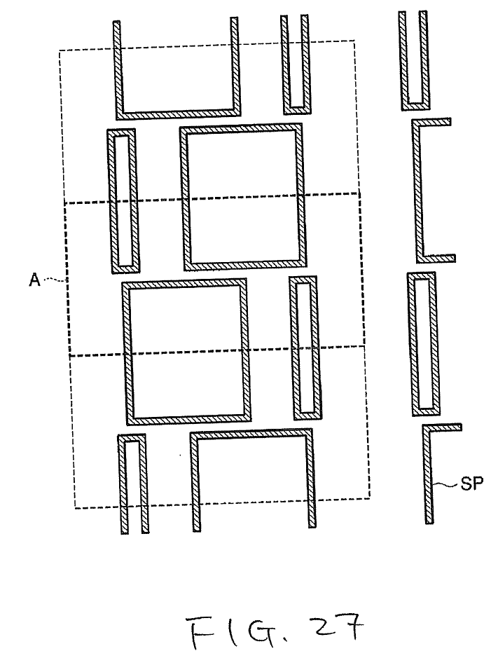

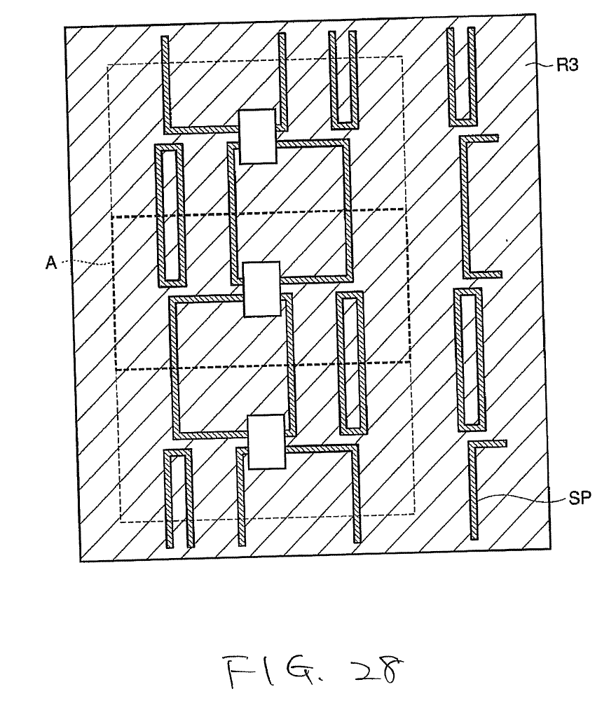

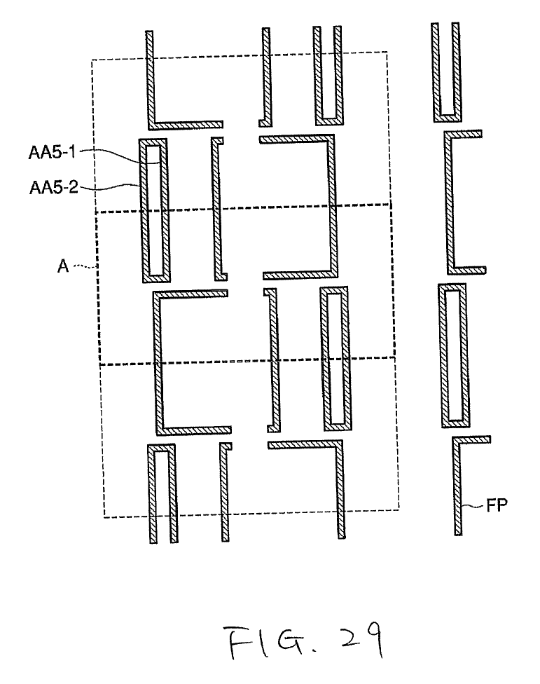

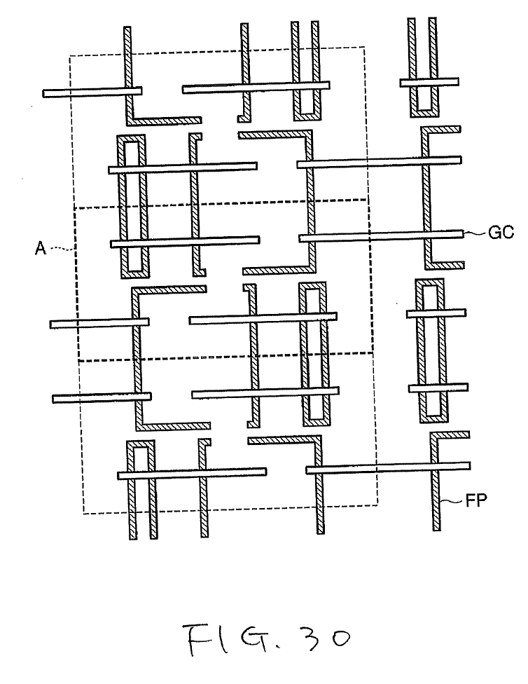

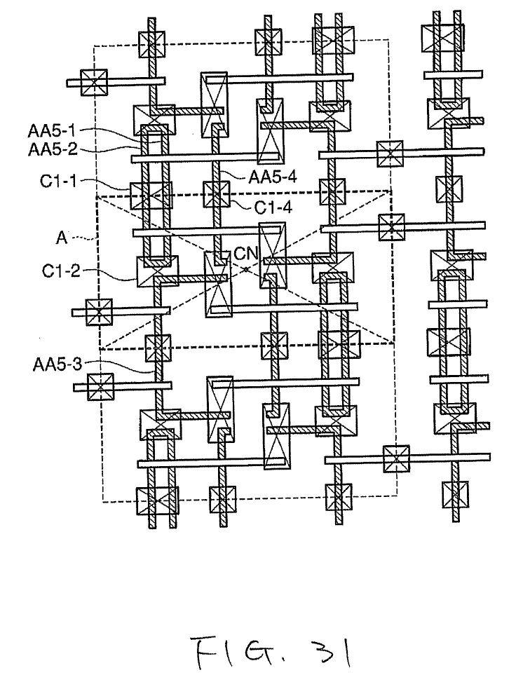

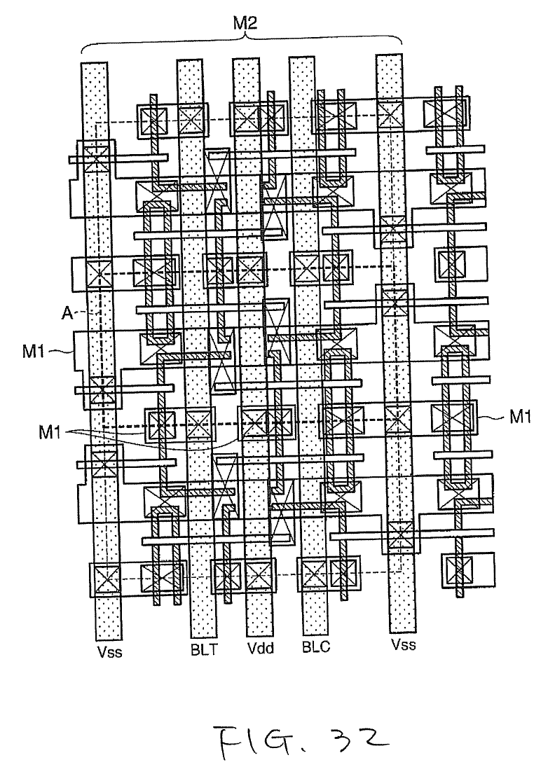

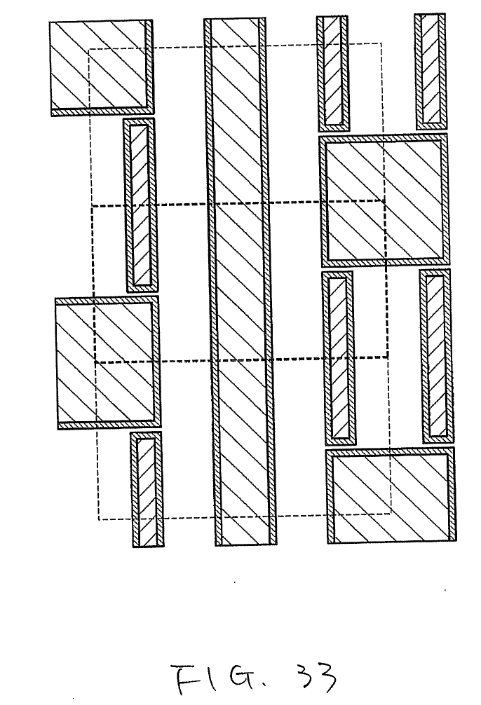

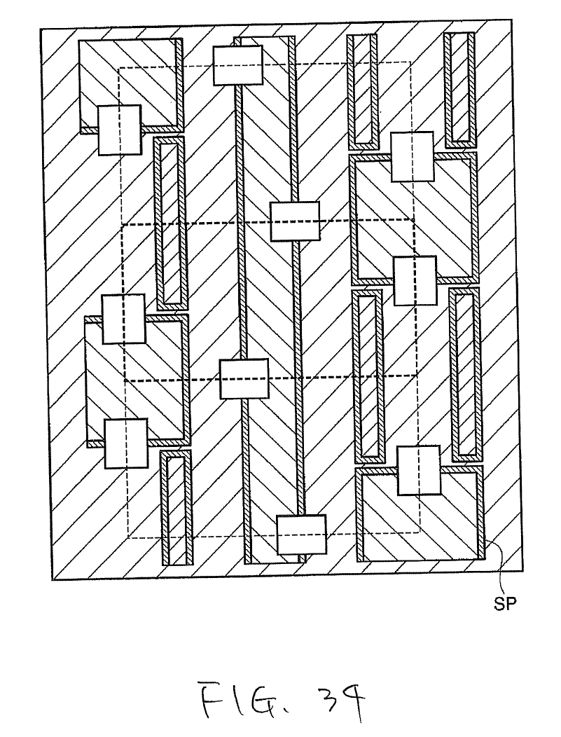

FIGS. 24 to 32 each are a plan view showing an example of a method of manufacturing (patterning) the SRAM according to the third embodiment.

Firstly, an insulating film to serve as dummy patterns is formed on the semiconductor substrate, and a negative resist film is subsequently applied on the insulating film. Then, the resist film is exposed so that a first dummy pattern D21 shown in FIG. 24 can be transferred thereon. Only such a thin pattern is transferred in this first exposure process. Here, the resist film is not developed, but the patterns are only formed as latent image. Thereafter, the resist film is further exposed so that a second dummy pattern D22 shown in FIG. 25 can be transferred thereon (double exposure). Note that the dummy patterns D21 and D22 are not overlapped with each other in this embodiment. This arrangement eliminates the need to take proximity correction into account, thus allowing the patterns to be sharply formed.

Then, the thus-patterned resist film is developed, and thereafter the insulating film is patterned so that the first and second dummy patterns D21 and D22 shown in FIG. 26 can be formed. Thereafter, a material to serve as sidewall patterns are stacked on the dummy patterns D21 and D22, and the semiconductor substrate. Subsequently, the above material is etched back so that sidewall patterns SP can remain on the sidewalls of the dummy patterns D21 and D22 as shown in FIG. 26.

Then, after the dummy patterns D21 and D22 are removed as shown FIG. 27, unnecessary portions of the sidewall patterns SP are removed by using, as a mask, a resist film R3 shown in FIG. 28. Furthermore, the silicon active regions under the unnecessary portions of the sidewall patterns SP are also removed by using the resist film R3 as a mask. Thereafter, the resist film R3 shown in FIG. 28 is peeled off. Subsequently, fin region patterns are formed by using the sidewall patterns SP as a mask. FIG. 29 shows the thus-formed fin region patterns FP. These fin region patterns FP are formed of the silicon active regions, almost all of which have the same size (width). Unlike the first embodiment, the two fin regions AA5-1 and AA5-2 in a driver transistor are connected with each other by fin regions formed in the direction approximately perpendicular to the channel length direction. Note that the section enclosed by a dashed line A represents an SRAM cell (unit cell).

Then, a gate insulating film, and a film to serve as gate electrodes are sequentially formed. Thereafter, these films are patterned to form gate electrodes GC as shown in FIG. 30. The gate electrodes GC are also formed by a sidewall pattern transfer method. Accordingly, all the transistors have the same gate length. Moreover, after the entire area is covered with an unillustrated insulating film, the insulating film is patterned to form contact regions as shown in FIG. 31. Here, only a contact region C1-1, to which the ground potential Vss is supplied, of the driver transistor is disposed in an offset layout. In other word, the contact region C1-1 is displaced from the middle of the fin regions AA5-1 and AA5-2 in a direction away from a contact region C1-4 that is disposed adjacent to the contact region C1-1 and to which a power supply voltage Vdd is supplied. With this arrangement, a necessary and sufficient distance can be maintained between the contact regions C1-1 and C1-4. One of the fin regions formed in the direction approximately perpendicular to the channel length direction to connect the fin regions AA5-1 and AA5-2 in the driver transistor and the portion (bent fin region), formed in the direction approximately perpendicular to the channel length direction, of the fin region AA5-3 in a transfer transistor are connected through the contact member in the contact region C1-2. The contact region C1-4 is formed on a part of the fin region AA5-4 in a load transistor. Furthermore, the bent regions, formed in the direction approximately perpendicular to the channel length direction, of the fin region AA5-4 in a load transistor and of the fin region AA5-3 in the transfer transistor are connected with each other through the contact member in a contact region C1-5.

Then, after an interlayer insulating film is formed on the semiconductor substrate, metal interconnections including first and second interconnections M1 and M2 are formed as shown in FIG. 32. Unlike the first and second embodiments, the fin region AA5-4 in the load transistor is electrically connected to the fin regions AA5-1 and AA5-2 in the driver transistor through the portion, formed in the direction approximately perpendicular to the channel length direction, of the fin region AA5-3, in this embodiment. This eliminates the need for a metal interconnection for connecting these regions, so that the entire metal interconnection in the SRAM cell can be formed of the two interconnection layers that are the first and second interconnections M1 and M2.

Note that the dummy patterns are formed by using a negative resist film herein, but the dummy patterns may be formed by using one or more positive resist films, as similar to the first embodiment. For example, after a positive resist film is applied on the insulating film, the resist film is exposed and developed so that the dummy pattern D21 shown in FIG. 24 can be transferred thereon. Then, after another positive resist film is further applied thereon, this resist film is exposed and developed so that the dummy pattern D22 shown in FIG. 25 can be transferred thereon. A resist film for forming the dummy patterns D21 and D22 may be formed in this manner. Alternatively, for example, after a positive resist film is applied on the insulating film, the resist film is exposed and developed so that the dummy patterns D21 and D22 shown in FIGS. 24 and 25 can be transferred thereon all at once. A resist film for forming the dummy patterns D21 and D22 may be formed by this method.

The third embodiment requires that the substrate be formed of an SOI substrate, but has advantages that the area of the cell can be reduced while a metal interconnection layer can be simplified since a well separation width can be reduced.

In a semiconductor device containing the SRAM cell manufactured as described above, the dimensional control of the fin widths is simplified while a difference in threshold voltage between the transistors in the SRAM cell can be controlled so that the current can be set to an appropriate value. Thus, the third embodiment makes it possible to manufacture a semiconductor device that includes an SRAM cell using FinFETs and having a sufficient static noise margin.

Hereinbelow, description will be given of an advantage of disposing each pair of the transfer transistors and the driver transistors in an offset layout instead of disposing them in line with each other. FIGS. 33 to 36 show processes of forming a layout in which one of the two fin regions of each driver transistor is disposed in line with the fin region of the corresponding transfer transistor.

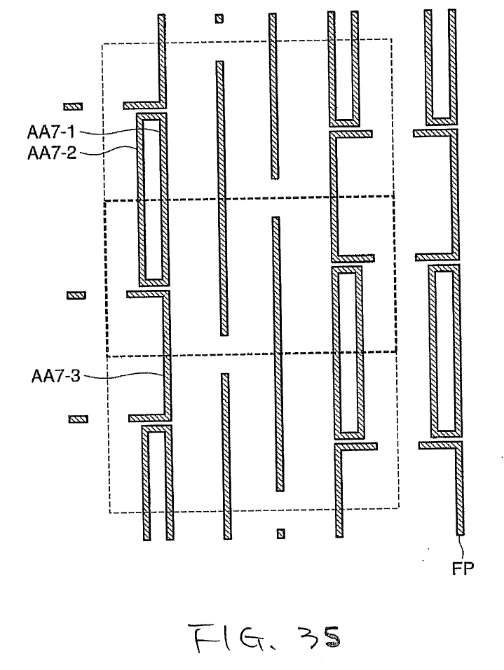

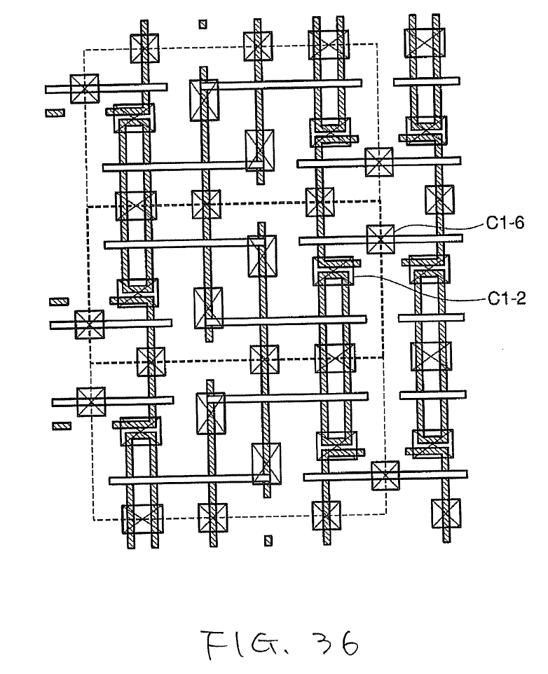

For example, sidewall patterns SP are formed on the sidewalls of a dummy pattern as shown in FIG. 33. Thereafter, a trimming mask for the sidewall patterns SP are formed on the sidewall patterns SP as shown in FIG. 34. In this event, it is difficult to perform the lithography of the trimming mask for the sidewall patterns SP, since distances between the dummy patterns are small. Here, a resist film is applied in the entire area, and thereafter openings are formed so that portions to be trimmed can be exposed. Accordingly, the lithography of the trimming mask for small dimensions is more difficult. FIG. 35 shows fin region patterns FP after trimming when the lithography of the trimming mask for the sidewall patterns SP has been successfully carried out. As is clear from FIG. 18, a sufficient resist opening width can be ensured when each pair of the transfer transistors and the driver transistors are disposed in an offset layout.

In addition, the contact region C1-6 on the gate electrode of the word line is placed close to the contact region C1-2 which connects a pair of the driver transistors and the transfer transistors as shown in FIG. 36, the clearance between the contact regions does not satisfy the minimum design rule. This is clear from the comparison between FIG. 36 and FIG. 21.

By contrast, although the contact region C1-1 which supplies ground potential Vss to the corresponding driver transistor is disposed closer to the contact region C1-4 which supplies power supply potential Vdd to the corresponding load transistor in FIG. 21 than in FIG. 36, the clearance between the contact regions C1-1 and C1-4 can satisfy the minimum design rule without increasing the area of the cell since the contact region C1-1 is disposed in an offset layout (displaced from the middle of the fin regions AA3-1 and AA3-2) as described above.

Hereinabove, description has been given of a case without an offset layout employed. In the above case, one fin region AA7-1 of the two fin regions of a driver transistor is disposed in line with the fin region AA7-3 of a transfer transistor, and the other fin region AA7-2 of the driver transistor is disposed in the outer side of the SRAM cell (a side opposite to a load transistor). Alternatively, suppose the case where the fin region AA7-2 of the driver transistor is disposed on the load transistor side here. In this case, even if the contact region C1-1 is disposed in an offset layout, any contact-to-contact clearance will not satisfy the minimum design rule, or if all the contact-to-contact clearances definitely satisfy the minimum design rule, the area of the cell will consequently be increased.

As described above, each of the embodiments of the present invention makes it possible to provide a semiconductor device that includes an SRAM cell using double-gate FinFETs and having a sufficient static noise margin and a method of producing the same. In addition, each of the embodiments of the present invention makes it possible to provide a method of applying, to an SRAM cell using FinFETs, lithography using a sidewall pattern transfer method capable of simplifying the dimensional control of the fin regions, and a method of forming a layout capable of reducing a parasitic resistance.

Embodiments of the invention have been described with reference to the examples. However, the invention is not limited thereto.

Other embodiments of the present invention will be apparent to those skilled in the art from consideration of the specification and practice of the invention disclosed herein. It is intended that the specification and example embodiments be considered as exemplary only, with a true scope and spirit of the invention being indicated by the following.

What is claimed is:

1. A semiconductor device, comprising:
a fin formed of a semiconductor layer protruding straight from a semiconductor substrate, the fin includes straight portion which extends in a direction in a plan view and a bent portion which extends in a direction different from the direction, the straight portion and the bent portion being continuously connected;
a gate insulating film provided on side surfaces of the straight portion of the fin;
a gate electrode provided on the gate insulating film;
source and drain regions provided in the straight portion of the fin so as to sandwich the gate electrode;
a contact region provided on the straight portion of the fin and the bent portion of the fin, the contact region being electrically connected to one of the source and drain regions; and
a contact member provided on the contact region of the fin so as to in contact with both of the straight portion and the bent portion of the contact region.

2. The semiconductor device according to claim 1, wherein the contact member connects the fin region and another fin region.

3. The semiconductor device according to claim 1, wherein the bent portion of the fin extends in a direction perpendicular to the direction which the straight portion extends to.

4. The semiconductor device according to claim 1, wherein the fin is loop shape in a plan view.

5. The semiconductor device according to claim 1, further comprising another contact region which is provided on the straight portion of the fin and electrically connected to the other one of the source and drain regions.

6. A semiconductor device, comprising:
a load transistor provided on a semiconductor substrate;
a transfer transistor provided on the semiconductor substrate; and
a driver transistor provided on the semiconductor substrate, wherein the driver transistor includes:
first and second fins each formed of a semiconductor layer protruding straight from the semiconductor substrate, each of the first and second fins includes straight portion which extends in a direction in a plan view and a bent portion which extends in a direction different from the direction, the straight portion and the bent portion being continuously connected, the first fin and the second fins extending substantially same direction;
a gate insulating film provided on side surfaces of the straight portion of each of the first and second fins;
a gate electrode provided on the gate insulating film;
first source and drain regions provided in the straight portion of the first fin so as to sandwich the gate electrode;
second source and drain regions provided in the straight portion of the second fin so as to sandwich the gate electrode;
a contact region provided on the straight portion of the first and second fins and the bent portion of the first and second fins, the contact region being electrically connected to one of the first and second source region and first and second drain region; and
a contact member provided on the contact region of the first and second fins so as to in contact with both of the straight portion and the bent portion of the contact region.

7. The semiconductor device according to claim 6, wherein
the transfer transistor has a third fin formed of a semiconductor layer protruding straight from the semiconductor substrate, and third fin extending same direction in a plan view as the first and second fins, and
the third fin is not provided in line with the first and second fins.

8. The semiconductor device according to claim 7, wherein the third fin is continuously connected to the bent portion of the first fin.

9. The semiconductor device according to claim 7, wherein the extended line from the third fin is provided between the straight portion of the first fin and second fin.

10. The semiconductor device according to claim 8, wherein the extended line from the third fin is provided between the straight portion of the first fin and second fin.

11. The semiconductor device according to claim 6, wherein the contact member connects the first and second fin region and another fin region.

12. The semiconductor device according to claim 6, wherein the bent portions of the first and second fin extend in a direction perpendicular to the direction which the straight portion extends to.

13. The semiconductor device according to claim 6, wherein the first and second fins are loop shape in a plan view.

14. The semiconductor device according to claim 6, further comprising another contact region which is provided on the straight portion of the first and second fins and electrically connected to the other one of the first and second source regions and the first and second drain regions, and another contact member provided on the another contact region of the first and second fins so as to in contact with the straight portion of the contact region

15. The semiconductor device according to claim 14, the another contact member is provided away from a middle of the first and second fins.
